(19) United States
(12) Patent Application Publication
(10) Pub. No.: US 2009/0096010 A1
(43) Pub. Date: Apr. 16, 2009

(54) NONVOLATILE MEMORY DEVICE AND FABRICATION METHOD THEREOF

(75) Inventor: Chan Sun Hyun, Icheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR, Icheon-Si (KR)

(21) Appl. No.: 11/963,908

(22) Filed: Dec. 24, 2007

(30) Foreign Application Priority Data
Oct. 10, 2007 (KR) 10-2007-102104

(51) Int. Cl. H01L 21/336; H01L 29/788

(52) U.S. Cl. 257/321; 438/594; 257/E29.3; 257/E21.422

(57) ABSTRACT

A nonvolatile memory device and a fabrication method thereof are disclosed. The nonvolatile memory device comprises a tunnel insulating film formed on an active region of a semiconductor substrate, a first conductive layer for a floating gate formed on the tunnel insulating film, a dielectric layer formed on the first conductive layer, a second conductive layer for a control gate formed on the dielectric layer, an etch-stop layer formed on the second conductive layer, and a gate electrode layer formed on the etch-stop layer. Accordingly, there is no difference in the degree to which the conductive layer under the gate electrode layer is etched when etching the gate electrode layer of the memory cell region and the peri region.

### CROSS-REFERENCE TO RELATED APPLICATION

Priority to Korean patent application number 10-2007-102104, filed on Oct. 10, 2007, which is incorporated by reference in its entirety, is claimed.

### BACKGROUND OF THE INVENTION

The invention generally relates to a nonvolatile memory device and a fabrication method thereof and, more particularly, to a NAND flash memory device and a fabrication method thereof.

In general, semiconductor memory devices can be classified into volatile memory devices and nonvolatile memory devices. Volatile memory devices include Dynamic Random Access Memory (DRAM) and Static Random Access Memory (SRAM), in which the input and output of data is fast, but data stored therein are lost when the device power supply is switched off. In contrast, nonvolatile memory devices include devices in which data stored therein are retained although the device power supply is switched off.

A flash memory device is a kind of a nonvolatile memory device, and is a highly integrated memory device, which was developed by combining the advantages of Erasable Programmable Read Only Memory (EPROM), which can be programmed and erased, and Electrically Erasable Programmable Read Only Memory (EEPROM), which can be electrically programmed and erased. The term “program” refers to an operation of writing data into a memory cell and “erase” refers to an operation of erasing data stored in a memory cell.

A NAND flash memory device is configured to perform the program operation by injecting electrons into the floating gate, and the erase operation employs Fowler/Nordheim (FN) tunneling to remove the electrons injected into the floating gate. The NAND flash memory device comprises a cell string in which a plurality of cells are connected in series. The NAND flash memory device is advantageous in that it has low power consumption when compared with a NOR flash memory device because current flowing within the cell string is low. The NAND flash memory device can be highly integrated compared with the NOR flash memory device, and is therefore suitable to fabricate large-capacity memory devices. Due to the above characteristics, the NAND flash memory device has recently been widely used.

The NAND flash memory device includes a memory cell transistor for storing data and a peripheral (“peri”) transistor for applying voltage to the memory cell transistor during operation. A plurality of memory cell transistors included in the NAND flash memory device are connected in a string structure. In order to select the string, select transistors, such as a source select transistor and a drain select transistor, are required.

In general, a NAND flash semiconductor substrate is divided into a memory cell region and a peri region. Memory cell transistors for storing data are formed in the memory cell region, and peri transistors for controlling the memory cell transistors are formed in the peri region. The semiconductor substrate is divided into the memory cell region and the peri region as described above, but the processes of forming the transistors in the memory cell region and the peri region are generally performed at the same time to increase the efficiency of the manufacturing process.

FIG. 2 is a scanning electron microscope (SEM) photograph of a memory device in which a loading effect was generated when fabricating a conventional nonvolatile memory device.

Referring to FIG. 2, a distance between adjacent transistors 201 is wide when compared with memory cell transistors 202. Thus, a dishing phenomenon may occur between the peri transistors 201 due to a loading effect during a gate etch process. In particular, FIG. 2 illustrates a step of etching a gate electrode layer 203. When the gate electrode layer 203 is etched, a conductive layer 204 between the peri transistors 201 rather than between the memory cell transistors 202 can be further etched. Accordingly, there occurs a predetermined height difference (indicated by L). The height difference in the conductive layer 204 remains intact in a subsequent gate etch process, so that the semiconductor substrate of a region where the memory cell transistor 202 is formed is over etched and damaged. Further, if the conductive layer 204 is thickly formed considering that the conductive layer 204 between the peri transistors 201 is further etched, the quantity of electric charges stored in the conductive layer 204 is increased and, therefore, an interference phenomenon between adjacent conductive layers 204 is further increased. In addition, if the thickness of the conductive layer 204 is increased, the height of a gate is increased and, therefore, a process for forming a contact plug between the gates becomes difficult.

### BRIEF SUMMARY OF THE INVENTION

According to the invention, an etch-stop layer is formed below a gate electrode layer in order to minimize the loading effect. Accordingly, there is no difference in the degree to which a conductive layer under the gate electrode layer is etched when etching the gate electrode layer of a memory cell region and a peri region.

A nonvolatile memory device according to an embodiment of the invention comprises a tunnel insulating film formed on an active region of a semiconductor substrate, a first conductive layer for a floating gate formed on the tunnel insulating film, a dielectric layer formed on the first conductive layer, a second conductive layer for a control gate formed on the dielectric layer, an etch-stop layer formed on the second conductive layer, and a gate electrode layer formed on the etch-stop layer.

The etch-stop layer preferably is formed from a conductive material, such as titanium (Ti) or titanium nitride (TiN). The etch-stop layer preferably is formed to a thickness of 100 angstrom to 200 angstrom. The gate electrode layer preferably is formed from tungsten (W) or tungsten silicide (WSiₓ).

A method of fabricating a nonvolatile memory device according to another embodiment of the invention includes providing a semiconductor substrate defining an active region, sequentially forming a tunnel insulating film, a first conductive layer, a dielectric layer, and a second conductive layer over the active region of the semiconductor substrate, forming an etch-stop layer on the second conductive layer, forming a gate electrode layer on the etch-stop layer, forming a gate mask pattern for gate patterning on the gate electrode layer, etching the gate electrode layer using the gate mask pattern until the etch-stop layer is exposed, removing the exposed etch-stop layer, and etching the second conductive layer, the dielectric layer and the first conductive layer.

The etch-stop layer preferably is formed from a conductive material, such as Ti or TiN. The etch-stop layer preferably is formed to a thickness of 100 angstrom to 200 angstrom. The gate electrode layer preferably is formed from W or WSiₓ using a dry etch process. Further, the gate electrode layer preferably is etched using a mixed gas of NF₃ gas and Cl₂ gas, or a mixed gas of SF₆ gas and Cl₂ gas as an etch gas at a temperature range of 20 degrees Celsius to 50 degrees Celsius. The exposed etch-stop layer preferably is removed using a dry etch process. Further, the exposed etch-stop layer preferably is removed using Cl₂ gas.

### BRIEF DESCRIPTION OF THE DRAWINGS

FIGS. 1A to 1H are sectional views illustrating a nonvolatile memory device and a fabrication method thereof according to an embodiment of the invention; and

FIG. 2 is a SEM photograph of a memory device in which the loading effect was generated when fabricating a conventional nonvolatile memory device.

### DESCRIPTION OF SPECIFIC EMBODIMENTS

Now, a specific embodiment according to the invention is described with reference to the accompanying drawings.

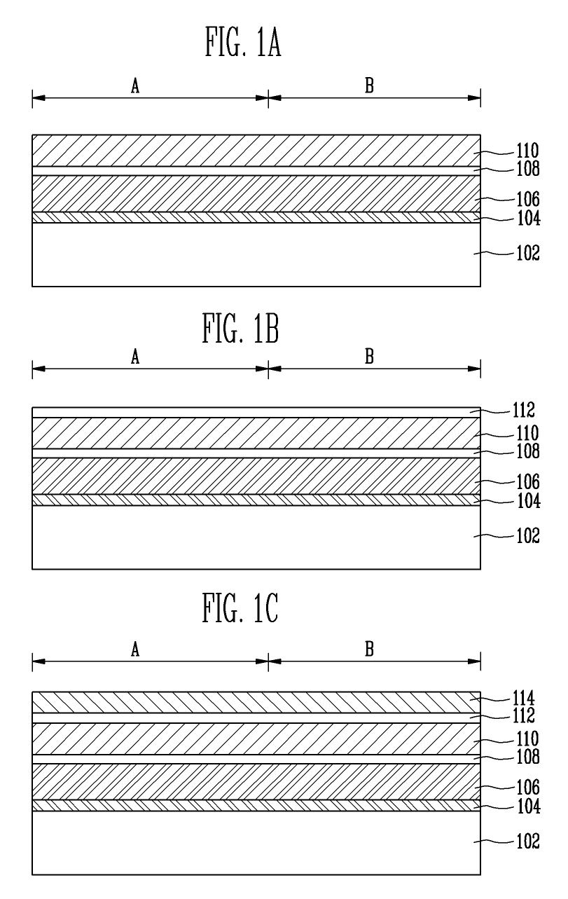

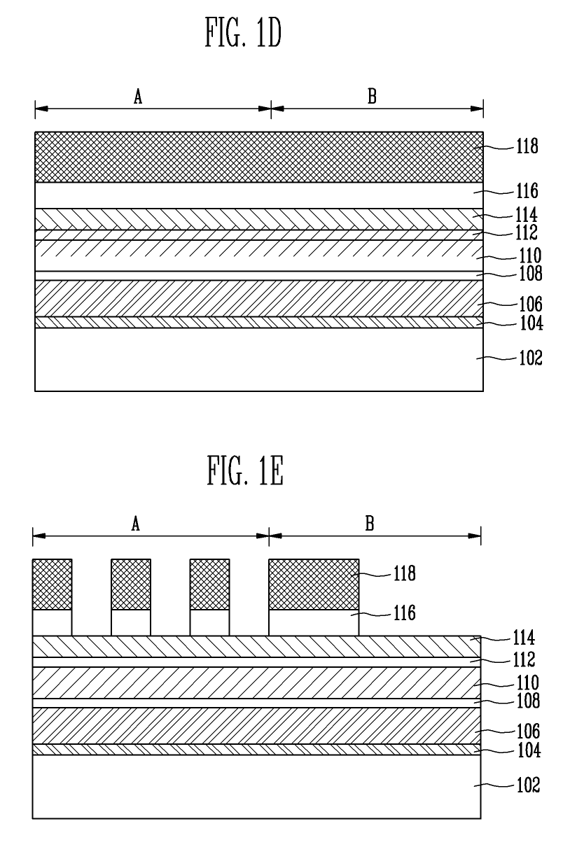

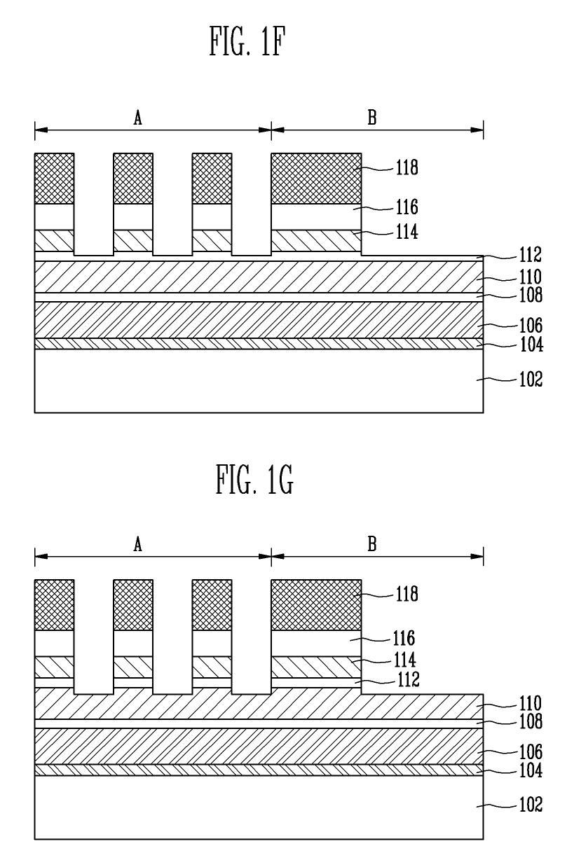

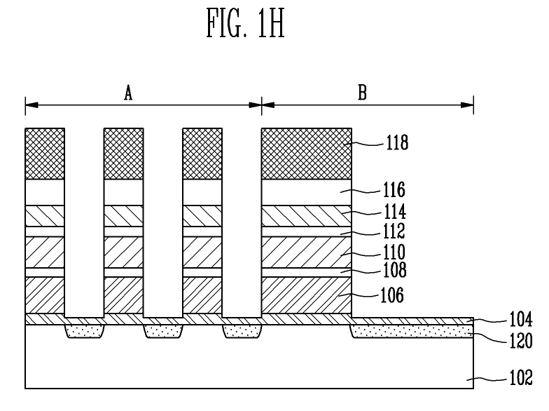

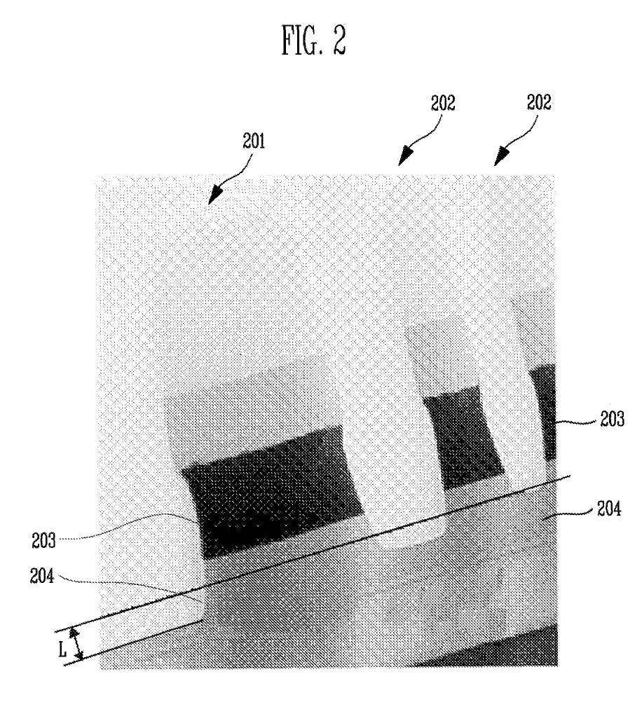

FIGS. 1A to 1H are sectional views illustrating a nonvolatile memory device and a fabrication method thereof according to an embodiment of the invention.

Referring to FIG. 1A, a screen oxide layer (not shown) is formed on a semiconductor substrate 102 defining an active region, including a memory cell region A and a peri region B. A well ion implantation process and a threshold voltage ion implantation process are performed on the semiconductor substrate 102. The well ion implantation process is performed in order to form a well region (not shown) in the semiconductor substrate 102, and the threshold voltage ion implantation process is performed so as to control the threshold voltage of semiconductor elements such as transistors. The screen oxide layer functions to prevent the interface of the semiconductor substrate 102 from being damaged in the well ion implantation process or the threshold voltage ion implantation process. Thus, the well region is formed in the semiconductor substrate 102 as a triple structure.

After the screen oxide layer is removed, a tunnel insulating film 104 is formed on the active region of the semiconductor substrate 102. In the tunnel insulating film 104, electrons can pass from the semiconductor substrate 102 below the tunnel insulating film 104 to a floating gate formed on the tunnel insulating film 104, or from the floating gate to the semiconductor substrate 102 below the tunnel insulating film 104 via FN tunneling. The tunnel insulating film 104 preferably is formed from an oxide film.

A first conductive layer 106 for the floating gate is formed on the tunnel insulating film 104. In a program operation, electrons of the semiconductor substrate 102 can be accumulated on the first conductive layer 106 through the tunnel insulating film 104. Alternatively, in an erase operation, charges stored in the first conductive layer 106 can be discharged toward the semiconductor substrate 102 through the tunnel insulating film 104. The first conductive layer 106 preferably is formed from polysilicon.

The first conductive layer 106, the tunnel insulating film 104, and part of the semiconductor substrate 102, formed in an isolation region (not shown) of the semiconductor substrate 102, are etched to form a trench (not shown). The trench is gap filled with an insulating material (for example, an oxide film), thus forming an isolation layer (not shown). A dielectric layer 108 is formed over the first conductive layer 106 and the isolation layer. The dielectric layer 108 may have an oxide/nitride/oxide (ONO) structure in which a first oxide film, a nitride film, and a second oxide film are sequentially layered. A second conductive layer 110 for a control gate is formed on the dielectric layer 108. The second conductive layer 110 preferably is formed to a thickness of 300 angstrom to 600 angstrom using polysilicon.

Referring to FIG. 1B, an etch-stop layer 112 is formed on the second conductive layer 110. The etch-stop layer 112 is used as a stop layer in a process for etching a gate electrode layer formed thereon. The etch-stop layer 112 preferably is formed to a thickness of 100 angstrom to 200 angstrom using a conductive material (for example, titanium (Ti) or titanium nitride (TiN)) so that the second conductive layer 110 formed therebelow is electrically connected to a gate electrode layer (not shown) formed thereon.

Referring to FIG. 1C, a gate electrode layer 114 is formed on the etch-stop layer 112. The gate electrode layer 114 preferably is formed from a metal material, for example tungsten (W) or tungsten silicide (WSiₓ).

Referring to FIG. 1D, in order to form a gate pattern mask for use in a gate etch process, a first hard mask 116 and a second hard mask 118 are formed over the gate electrode layer 114. The first hard mask 116 preferably is formed from a Tetra Ethyl OrthoSilicate (TEOS) oxide film, and the second hard mask 118 preferably is formed from amorphous carbon.

Referring to FIG. 1E, a photoresist pattern (not shown) is formed on the second hard mask 118. The first hard mask 116 and the second hard mask 118 are patterned to form a gate mask pattern. The first hard mask 116 and the second hard mask 118 are formed for a gate patterning process. In particular, portions of the first hard mask 116 and the second hard mask 118 (which correspond to the isolation regions of the semiconductor substrate 102) are opened. At this time, the gate mask pattern of the peri region B is larger than that of the memory cell region A.

Referring to FIG. 1F, the gate electrode layer 114 is patterned by performing a gate etch process employing the first hard mask 116 and the second hard mask 118. The etch process of patterning the gate electrode layer 114 preferably is performed by dry etching with a mixed gas of NF₃ gas and Cl₂ gas, or a mixed gas of SF₆ gas and Cl₂ gas as an etch gas.

At this time, if the etch-stop layer 112 is exposed as the gate electrode layer 114 is patterned, flourine included in the etch gas reacts with titanium included in the etch-stop layer 112, thus forming TiF₄. Accordingly, the patterning process of the gate electrode layer 114 is stopped. In order to further increase the etch selectivity of TiF₄, the etch process preferably is performed in a temperature range of 20 degrees Celsius to 50 degrees Celsius.

As described above, the patterning process of the gate electrode layer 114 is stopped as the etch-stop layer 112 is exposed. Accordingly, a dishing phenomenon in which the second conductive layer 110 of the peri region B (i.e., where the gate distance is wider) is more etched than the second conductive layer 110 of the memory cell region A can be prevented.

Referring to FIG. 1G, a dry etch process for removing the exposed etch-stop layer 112 using Cl₂ gas is performed. The Cl₂ gas reacts with titanium included in the etch-stop layer, thus forming TiCl₄. At this time, the exposed etch-stop layer 112 can be removed easily since TiCl₄ has a melting point higher than that of TiF₄. Consequently, the second conductive layer 110, which is formed below the exposed etch-stop layer 112, is exposed.

Referring to FIG. 1H, after the exposed second conductive layer 110 is patterned by continuously performing the gate etch process, the dielectric layer 108 and the first conductive layer 106 formed under the exposed second conductive layer 110 are also patterned. Consequently, a gate of the memory cell region A and the peri region B is formed. An ion implantation process is then performed on the semiconductor substrate 102 between the gates, thus forming junction regions 120.

As described above, according to the invention, there is no difference in the degree to which the conductive layer under the gate electrode layer is etched when etching the gate electrode layer of the memory cell region and the peri region. Accordingly, since it is not necessary to form the conductive layer more thickly, an interference phenomenon between the conductive layers can be reduced. Further, since a gate height is reduced, a process for forming a contact plug between the gates is facilitated.

Although the foregoing description has been made with reference to a specific embodiment, it is to be understood that changes and modifications of the invention may be made by the ordinarily skilled artisan without departing from the spirit and scope of the invention as defined in the appended claims.

What is claimed is:

1. A nonvolatile memory device, comprising:
a tunnel insulating film formed on an active region of a semiconductor substrate;
a first conductive layer for a floating gate formed on the tunnel insulating film;
a dielectric layer formed on the first conductive layer;
a second conductive layer for a control gate formed on the dielectric layer;
an etch-stop layer formed on the second conductive layer; and
a gate electrode layer formed on the etch-stop layer.

2. The nonvolatile memory device of claim 1, wherein the etch-stop layer comprises a conductive material.

3. The nonvolatile memory device of claim 1, wherein the etch-stop layer is selected from the group consisting of titanium (Ti) and titanium nitride (TiN).

4. The nonvolatile memory device of claim 1, wherein the etch-stop layer has a thickness of 100 angstrom to 200 angstrom.

5. The nonvolatile memory device of claim 1, wherein the gate electrode layer is selected from the group consisting of tungsten (W) and tungsten silicide (WSiₓ).

6. A method of fabricating a nonvolatile memory device, the method comprising:
providing a semiconductor substrate defining an active region;
sequentially forming a tunnel insulating film, a first conductive layer, a dielectric layer, and a second conductive layer over the active region of the semiconductor substrate;
forming an etch-stop layer on the second conductive layer;
forming a gate electrode layer on the etch-stop layer;
forming a gate mask pattern for gate patterning on the gate electrode layer;
etching the gate electrode layer using the gate mask pattern until the etch-stop layer is exposed;
removing the exposed etch-stop layer; and
etching the second conductive layer, the dielectric layer, and the first conductive layer.

7. The method of claim 6, wherein the etch-stop layer comprises a conductive material.

8. The method of claim 6, wherein the etch-stop layer is selected from the group consisting of titanium (Ti) and titanium nitride (TiN).

9. The method of claim 6, comprising forming the etch-stop layer to a thickness of 100 angstrom to 200 angstrom.

10. The method of claim 6, wherein the gate electrode layer is selected from the group consisting of tungsten (W) and tungsten silicide (WSiₓ).

11. The method of claim 6, wherein etching the gate electrode layer comprises performing a dry etch process.

12. The method of claim 6, wherein etching the gate electrode layer comprises using an etch gas selected from the group consisting of a mixed gas of NF₃ gas and Cl₂ gas, and a mixed gas of SF₆ gas and Cl₂ gas.

13. The method of claim 6, comprising etching the gate electrode layer at a temperature of 20 degrees Celsius to 50 degrees Celsius.

14. The method of claim 6, comprising removing the exposed etch-stop layer using a dry etch process.

15. The method of claim 6, comprising removing the exposed etch-stop layer using Cl₂ gas.
